(19) United States
(12) Patent Application Publication
(10) Pub. No.: US 2025/0014802 A1
(43) Pub. Date: Jan. 9, 2025

(54) COMMON MODE NOISE FILTER

(71) Applicant: Panasonic Intellectual Property Management Co., Ltd., Osaka (JP)

(72) Inventors: Naoto YABUUCHI, Osaka (JP); Yoshiharu OOMORI, Osaka (JP); Yutaka TAGUCHI, Osaka (JP); Takuji KAWASHIMA, Fukui (JP)

(21) Appl. No.: 18/710,533

(22) PCT Filed: Nov. 24, 2022
(86) PCT No.: PCT/JP2022/043360

§ 371 Date: May 15, 2024

(30) Foreign Application Priority Data
Nov. 26, 2021 (JP) 2021-192485

(51) Int. Cl. H01F 27/28; H01F 27/29; H01F 27/32; H03H 7/01

(52) U.S. Cl. CPC H01F 27/2804; H01F 27/292; H01F 27/323; H01F 2027/2809; H03H 7/01

(57) ABSTRACT

A common mode noise filter includes: a plurality of insulator layers; and a first coil conductor, a second coil conductor, a third coil conductor, a fourth coil conductor, a fifth coil conductor, and a sixth coil conductor. A first interval I1 measured in an upward/downward direction from an upper surface of the first coil conductor to a lower surface of the third coil conductor, a second interval I2 measured in the upward/downward direction from an upper surface of the fourth coil conductor to a lower surface of the sixth coil conductor, and a third interval I3 measured in the upward/downward direction from the lower surface of the third coil conductor to the upper surface of the fourth coil conductor satisfy I1<I3 and I2<I3.

### TECHNICAL FIELD

The present disclosure generally relates to a common mode noise filter. More particularly, the present disclosure relates to a common mode noise filter including three coils.

### BACKGROUND ART

Patent Literature 1 discloses a common mode noise filter including: a plurality of non-magnetic layers which are stacked one on top of another in a stacking direction; and first, second, and third coils which are respectively provided for the plurality of non-magnetic layers, and which are independent of each other. The first, second, and third coils have first, second, and third coil conductors, respectively. The first and third coil conductors are arranged to shift from the second coil conductor in a direction perpendicular to the stacking direction.

In the common mode noise filter of Patent Literature 1, the balance between signals extracted from the respective coils may be lost to cause a decline in the mode conversion characteristics thereof in some cases.

### CITATION LIST

### Patent Literature

Patent Literature 1: WO 2016/132410 A1

### SUMMARY OF INVENTION

An object of the present disclosure is to reduce the chances of causing a decline in the mode conversion characteristics of a common mode noise filter.

A common mode noise filter according to an aspect of the present disclosure includes: a plurality of insulator layers stacked one on top of another in an upward/downward direction; and a first coil conductor, a second coil conductor, a third coil conductor, a fourth coil conductor, a fifth coil conductor, and a sixth coil conductor provided for the plurality of insulator layers. A first coil, a second coil, and a third coil are formed by the first coil conductor, the second coil conductor, the third coil conductor, the fourth coil conductor, the fifth coil conductor, and the sixth coil conductor. The first coil is formed by electrically connecting one coil conductor selected from the group consisting of the first coil conductor and the second coil conductor to the fourth coil conductor. The second coil is formed by electrically connecting a remaining coil conductor selected from the group consisting of the first coil conductor and the second coil conductor to one coil conductor selected from the group consisting of the fifth coil conductor and the sixth coil conductor. The third coil is formed by electrically connecting the third coil conductor to a remaining coil conductor selected from the group consisting of the fifth coil conductor and the sixth coil conductor. The first coil conductor, the second coil conductor, the third coil conductor, the fourth coil conductor, the fifth coil conductor, and the sixth coil conductor are arranged in this order from top to bottom. A first interval I1 measured in the upward/downward direction from an upper surface of the first coil conductor to a lower surface of the third coil conductor, a second interval I2 measured in the upward/downward direction from an upper surface of the fourth coil conductor to a lower surface of the sixth coil conductor, and a third interval I3 measured in the upward/downward direction from the lower surface of the third coil conductor to the upper surface of the fourth coil conductor satisfy I1<I3 and I2<I3.

### BRIEF DESCRIPTION OF DRAWINGS

FIG. 1 is a sectional side elevation covering first turn parts and second turn parts of coils of a common mode noise filter according to an exemplary embodiment;

FIG. 2 is a perspective view of the common mode noise filter;

FIG. 3 is an exploded perspective view of the common mode noise filter;

FIG. 4 is a top cross-sectional view of the common mode noise filter;

FIG. 5 is a schematic representation illustrating an arrangement of a first coil conductor and a second coil conductor in the common mode noise filter;

FIG. 6 is a schematic representation illustrating an arrangement of a third coil conductor and the second coil conductor in the common mode noise filter;

FIG. 7 is a graph showing differential/common mode conversion characteristics of a common mode noise filter according to a first comparative example;

FIG. 8 is a graph showing differential/common mode conversion characteristics of a common mode noise filter according to a first reference example;

FIG. 9 is a graph showing respective differential/common mode conversion characteristics of a common mode noise filter according to a second comparative example and a common mode noise filter according to a second reference example;

FIG. 10 is a sectional side elevation covering first turn parts and second turn parts of coils of a common mode noise filter according to a first variation;

FIG. 11 is a perspective view of the common mode noise filter;

FIG. 12 is an exploded perspective view of the common mode noise filter; and

FIG. 13 is a graph showing a differential/common mode conversion characteristics of a common mode noise filter according to a third reference example.

### DESCRIPTION OF EMBODIMENTS

### Embodiment

A common mode noise filter according to an exemplary embodiment will now be described with reference to the accompanying drawings. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

### (Overview)

The present disclosure relates to a common mode noise filter. The common mode noise filter attenuates common mode noise components of a given signal while allowing differential mode components of the signal to pass through the common mode noise filter. The common mode noise filter is mounted on either a circuit board of an electronic device or an electronic component, for example.

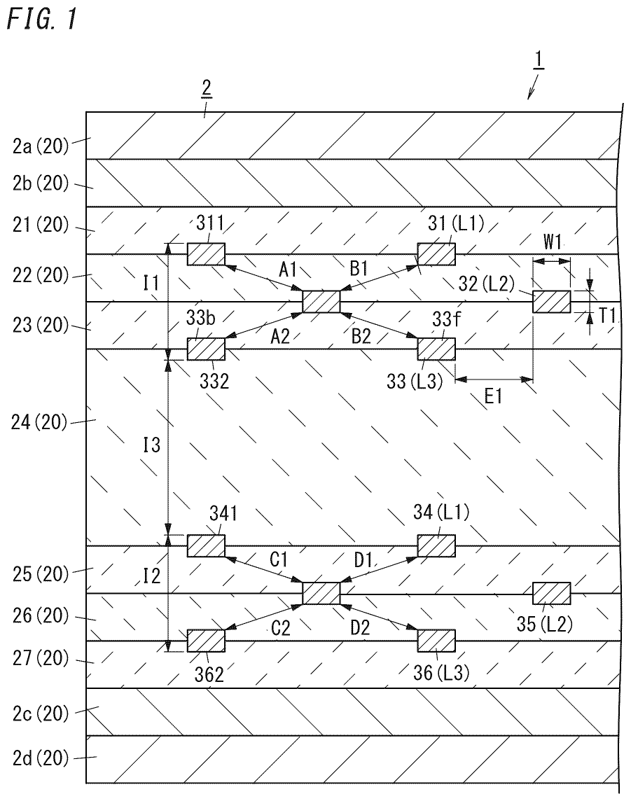

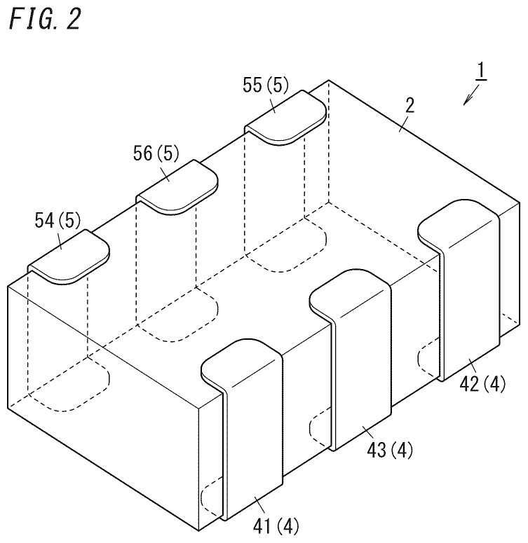

As shown in FIGS. 1 and 2, the common mode noise filter 1 according to this embodiment includes three coils (namely, a first coil L1, a second coil L2, and a third coil L3), three first terminals 4, and three second terminals 5. A first end of each coil is connected to a corresponding one of the first terminals 4 and a second end thereof is connected to a corresponding one of the second terminals 5. If the three first terminals 4 are used as signal input terminals, then the three second terminals 5 are used as signal output terminals. If the three second terminals 5 are used as signal input terminals, then the three first terminals 4 are used as signal output terminals.

The common mode noise filter 1 is compliant with the MIPI C-PHY standard. The common mode noise filter 1 is implemented on a transmission line for transmitting differential signals. The transmission line includes three input lines and three output lines. The three input lines are respectively electrically connected to the three input terminals of the common mode noise filter 1. The three output lines are respectively electrically connected to the three output terminals of the common mode noise filter 1. A signal supplied to each input terminal is passed through a corresponding one of the coils and delivered from a corresponding one of the output terminals.

A circuit provided for the three output lines calculates differential signals between respective pairs of the three output lines (i.e., obtains three differential signals). Stray capacitance is produced in each of the three coils of the common mode noise filter 1. A dispersion in stray capacitance from one coil to another is expressed as noise in each of the three differential signals, thus causing a decline in the mode conversion characteristics of the common mode noise filter 1. Thus, the problem to be overcome by the present disclosure is to reduce the chances of causing a decline in the mode conversion characteristics by reducing the dispersion in stray capacitance between the respective coils. In this embodiment, the mode conversion characteristics are evaluated by reference to a differential/common mode conversion characteristic (Scd21) and the magnitude of common mode attenuation (Scc21). Alternatively, the mode conversion characteristics may also be evaluated by reference to the common/differential mode conversion characteristic (Sdc21).

To reduce the chances of causing a decline in the mode conversion characteristics, a common mode noise filter 1 according to this embodiment includes: a plurality of insulator layers 20 stacked one on top of another in an upward/downward direction; and a first coil conductor 31, a second coil conductor 32, a third coil conductor 33, a fourth coil conductor 34, a fifth coil conductor 35, and a sixth coil conductor 36 provided for the plurality of insulator layers 20 as shown in FIG. 1. A first coil L1, a second coil L2, and a third coil L3 are formed by the first coil conductor 31, the second coil conductor 32, the third coil conductor 33, the fourth coil conductor 34, the fifth coil conductor 35, and the sixth coil conductor 36. The first coil L1 is formed by electrically connecting one coil conductor selected from the first coil conductor 31 and the second coil conductor 32 to the fourth coil conductor 34. The second coil L2 is formed by electrically connecting a remaining coil conductor selected from the first coil conductor 31 and the second coil conductor 32 to one coil conductor selected from the fifth coil conductor 35 and the sixth coil conductor 36. The third coil L3 is formed by electrically connecting the third coil conductor 33 to a remaining coil conductor selected from the fifth coil conductor 35 and the sixth coil conductor 36. The first coil conductor 31, the second coil conductor 32, the third coil conductor 33, the fourth coil conductor 34, the fifth coil conductor 35, and the sixth coil conductor 36 are arranged in this order from top to bottom. A first interval I1 measured in the upward/downward direction from an upper surface 311 of the first coil conductor 31 to a lower surface 332 of the third coil conductor 33, a second interval I2 measured in the upward/downward direction from an upper surface 341 of the fourth coil conductor 34 to a lower surface 362 of the sixth coil conductor 36, and a third interval I3 measured in the upward/downward direction from the lower surface 332 of the third coil conductor 33 to the upper surface 341 of the fourth coil conductor 34 satisfy I1<I3 and I2<I3.

The stray capacitance produced between two coils may cause a decline in the differential signal between the two coils. According to this embodiment, the third interval I3 measured in the upward/downward direction between the third coil conductor 33 and the fourth coil conductor 34 is so long that the stray capacitance to be produced between the third coil conductor 33 and the fourth coil conductor 34 is insignificant. This may reduce the chances of causing a more significant decline in the differential signal between the output signal of a coil including the third coil conductor 33 and the output signal of a coil including the fourth coil conductor 34 than in other differential signals. That is to say, this embodiment may reduce the chances of causing a decline in the mode conversion characteristics of the common mode noise filter 1.

Specifically, in this embodiment, the first coil L1 includes the first coil conductor 31 and the fourth coil conductor 34 electrically connected to the first coil conductor 31. The second coil L2 includes the second coil conductor 32 and the fifth coil conductor 35 electrically connected to the second coil conductor 32. The third coil L3 includes the third coil conductor 33 and the sixth coil conductor 36 electrically connected to the third coil conductor 33. According to this configuration, if the first coil conductor 31, the second coil conductor 32, the third coil conductor 33, the fourth coil conductor 34, the fifth coil conductor 35, and the sixth coil conductor 36 were arranged at regular intervals in the upward/downward direction, then more significant stray capacitance would be produced between the third coil conductor 33 and the fourth coil conductor 34 than in FIG. 1. That is to say, the stray capacitance produced between the first coil L1 and the third coil L3 would be greater than the stray capacitance produced between the first coil L1 and the second coil L2 and the stray capacitance produced between the second coil L2 and the third coil L3. In that case, the (third) differential signal between the output signal of the first coil L1 and the output signal of the third coil L3 would be more likely to deteriorate than the (first) differential signal between the output signal of the second coil L2 and the output signal of the first coil L1 or the (second) differential signal between the output signal of the second coil L2 and the output signal of the third coil L3. In a high frequency range, in particular, the stray capacitance has so significant effect that the third differential signal would be highly likely to deteriorate. If the third differential signal deteriorated to a more significant degree than the first differential signal or the second differential signal, then the balance between the first to third differential signal would be lost, thus causing a decline in the mode conversion characteristics of the common mode noise filter 1. According to this embodiment, the stray capacitance is reduced by leaving a sufficiently long third interval I3 in the upward/downward direction between the lower surface 332 of the third coil conductor 33 and the upper surface 341 of the fourth coil conductor 34, thereby reducing the chances of causing a decline in the mode conversion characteristics of the common mode noise filter 1.

Note that the terms “up” and “down” as used herein only refer to relative positional relationship between respective constituent elements of the common mode noise filter 1 and should not be construed as limiting the direction in which the common mode noise filter 1 may be used. Rather, the common mode noise filter 1 may also be used to have such an orientation that makes “down” as used herein “up,” “forward,” “backward,” “left,” or “right,” for example.

In the following description, the first coil conductor 31, the second coil conductor 32, the third coil conductor 33, the fourth coil conductor 34, the fifth coil conductor 35, and the sixth coil conductor 36 will be hereinafter collectively referred to as “coil conductors.”

### (Details)

### (1) Constituent Elements

As shown in FIGS. 1-3, the common mode noise filter 1 according to this embodiment includes a multilayer structure 2, a single first coil L1, a single second coil L2, a single third coil L3, three first terminals 4, and three second terminals 5. The multilayer structure 2 is formed integrally with the first coil L1, the second coil L2, the third coil L3, the three first terminals 4, and the three second terminals 5.

### (2) Multilayer Structure

As shown in FIG. 1, the multilayer structure 2 includes a plurality of (e.g., eleven in the example shown in FIG. 1) insulator layers 20. The plurality of insulator layers 20 are stacked one on top of another in the upward/downward direction. In top view, the plurality of insulator layers 20 have the same shape. Specifically, in top view, these insulator layers 20 have a rectangular shape. Each of these insulator layers 20 has a rectangular parallelepiped shape. The multilayer structure 2 is formed to have a rectangular parallelepiped shape as a whole by stacking these insulator layers 20 one on top of another.

The plurality of insulator layers 20 includes insulator layers 21, 22, 23, 24, 25, 26, 27, 2a, 2b, 2c, and 2d. The plurality of insulator layers 20 are stacked one on top of another in the orders of the layers 2a, 2b, 21, 22, 23, 24, 25, 26, 27, 2c, and 2d. Optionally, two adjacent insulator layers 20 may be integrated together to the point that makes the boundary between the two layers visually unrecognizable.

All of these insulator layers 20 but the insulator layer 24 have an equal thickness. The thickness of the insulator layer 24 is greater than that of the other insulator layers 20. The thickness of the insulator layer 24 is greater than twice, but less than five times, as large as the thickness of the other insulator layers 20.

The insulator layers 21-27 are non-magnetic layers. The non-magnetic layers may contain, for example, glass ceramic as their material.

The insulator layers 2a-2d are magnetic layers. The magnetic layers may contain, for example, ferrite as their material.

### (3) Three First Terminals and Three Second Terminals

As shown in FIG. 2, the three first terminals 4 and the three second terminals 5 are formed on side surfaces (i.e., surfaces aligned with the upward/downward direction) of the multilayer structure 2. One surface, having the three first terminals 4, of the multilayer structure 2 is opposite from another surface, having the three second terminals 5, of the multilayer structure 2.

The three first terminals 4 and the three second terminals 5 are made of an electrically conductive material such as silver.

The three first terminals 4 are provided one to one for the first coil conductor 31, the second coil conductor 32, and the third coil conductor 33, respectively. The three second terminals 5 are provided one to one for the fourth coil conductor 34, the fifth coil conductor 35, and the sixth coil conductor 36, respectively. Each of the three first terminals 4 and the three second terminals 5 is connected to the first end of a corresponding coil conductor. This makes each of the three first terminals 4 and the three second terminals 5 electrically connected to its corresponding coil conductor.

In the following description, the three first terminals 4 will be hereinafter referred to, as needed, as “first terminals 41, 42, 43,” respectively. The first terminal 41 is electrically connected to the first coil conductor 31. The first terminal 42 is electrically connected to the second coil conductor 32. The first terminal 43 is electrically connected to the third coil conductor 33.

In the following description, the three second terminals 5 will be hereinafter referred to, as needed, as “second terminals 54, 55, 56,” respectively. The second terminal 54 is electrically connected to the fourth coil conductor 34. The second terminal 55 is electrically connected to the fifth coil conductor 35. The second terminal 56 is electrically connected to the sixth coil conductor 36.

### (4) Three Coils

### (4.1) Constituent Elements

The first coil L1, the second coil L2, and the third coil L3 are magnetically coupled to each other.

As described above, the first coil L1 includes the first coil conductor 31 and the fourth coil conductor 34. The second coil L2 includes the second coil conductor 32 and the fifth coil conductor 35. The third coil L3 includes the third coil conductor 33 and the sixth coil conductor 36.

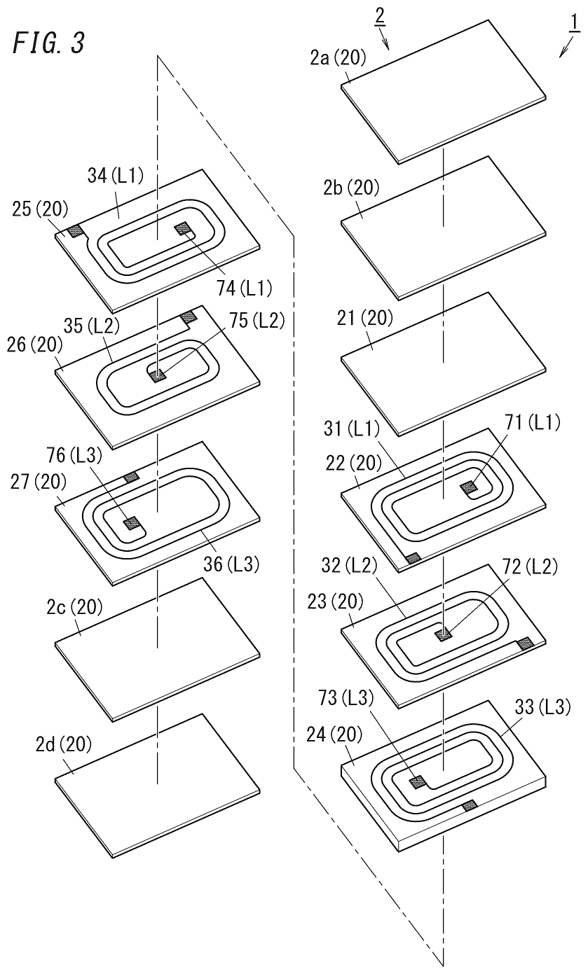

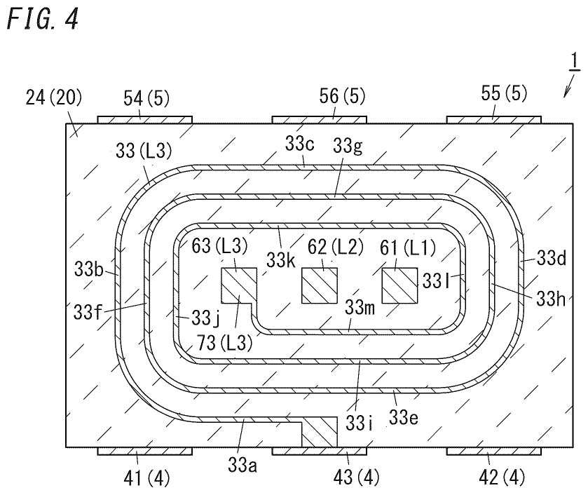

As shown in FIGS. 3 and 4, the first coil L1 further includes pad conductors 71, 74 and a through hole conductor 61. The second coil L2 further includes pad conductors 72, 75 and a through hole conductor 62. The third coil L3 further includes pad conductors 73, 76 and a through hole conductor 63.

### (4.2) Three Through Hole Conductors

Each of the three through hole conductors 61, 62, 63 is arranged to run through two or more layers out of the plurality of insulator layers 20. In top view, the through hole conductors 61, 62, 63 are arranged side by side in one direction. In top view, the through hole conductor 62 is interposed between the through hole conductor 61 and the through hole conductor 63.

Each of the through hole conductors 61, 62, 63 is connected to the pad conductors 71 (72, 73, 74, 75, or 76) provided at the respective second ends of its corresponding two coil conductors. This allows each of the through hole conductors 61, 62, 63 to electrically connect its corresponding two coil conductors to each other. As used herein, the “second end” refers to an end of a coil conductor opposite from the first end thereof connected to either the first terminal 4 or the second terminal 5.

The through hole conductor 61 electrically connects the two coil conductors of the first coil L1. That is to say, the through hole conductor 61 electrically connects the first coil conductor 31 and the fourth coil conductor 34. The through hole conductor 61 penetrates through the insulator layers 22-24.

The through hole conductor 62 electrically connects the two coil conductors of the second coil L2. That is to say, the through hole conductor 62 electrically connects the second coil conductor 32 and the fifth coil conductor 35. The through hole conductor 62 penetrates through the insulator layers 23-25.

The through hole conductor 63 electrically connects the two coil conductors of the third coil L3. That is to say, the through hole conductor 63 electrically connects the third coil conductor 33 and the sixth coil conductor 36. The through hole conductor 63 penetrates through the insulator layers 24-26.

The multilayer structure 2 has three through holes to provide the three through hole conductors 61, 62, 63, respectively. Each of the through holes penetrates through at least one of the plurality of insulator layers 20. Each of the through hole conductors 61, 62, 63 is formed by sintering conductive paste that fills a corresponding one of the through holes.

### (4.3) Pad Conductors

The pad conductors 71-76 are provided for the first coil conductor 31, the second coil conductor 32, the third coil conductor 33, the fourth coil conductor 34, the fifth coil conductor 35, and the sixth coil conductor 36, respectively. Each of the pad conductors 71-76 is provided at the second end of its corresponding coil conductor. The pad conductors 71, 74 are arranged one on top of the other. The pad conductors 72, 75 are arranged one on top of the other. The pad conductors 73, 76 are arranged one on top of the other.

### (4.4) Coil Conductors

Each of the coil conductors is made of an electrically conductive material such as silver. The coil conductor is formed in the shape of a plate. The thickness axis of the coil conductor is aligned with the upward/downward direction. A normal to the upper surface of the coil conductor and a normal to the lower surface of the coil conductor are also aligned with the upward/downward direction. The coil conductor is formed in the shape of a spiral around the center axis (virtual axis) aligned with the upward/downward direction. In top view, the spiral direction (i.e., winding direction) of the first coil conductor 31, the second coil conductor 32, and the third coil conductor 33 is opposite from the spiral direction of the fourth coil conductor 34, the fifth coil conductor 35, and the sixth coil conductor 36. For example, in FIG. 3, the first coil conductor 31, the second coil conductor 32, and the third coil conductor 33 spiral in the clockwise direction (i.e., spiral inward from outside the spiral). The fourth coil conductor 34, the fifth coil conductor 35, and the sixth coil conductor 36 spiral in the counterclockwise direction (i.e., spiral outward from inside the spiral).

The number of turns of each coil conductor is greater than two turns and generally equal to or less than three turns. An (N+1)^{th} turn part of each coil conductor is provided to be separated from an N^{th} turn part of the coil conductor, where N is an arbitrary value as long as N is equal to or greater than 1 and N+1 is equal to or less than the number of turns of the coil conductor. Take the third coil conductor 33, for example, N=1, 2. Therefore, the configuration satisfies the condition “the (N+1)^{th} turn part of the third coil conductor 33 is separated from the N^{th} turn part of the third coil conductor 33” both when N=1 and when N=2.

Each coil conductor may be formed on the surface of its corresponding insulator layer 20 by, for example, plating transfer technique. Each coil conductor is provided to be embedded in its corresponding insulator layer 20. The first coil conductor 31 is formed between the insulator layers 21, 22. The second coil conductor 32 is formed between the insulator layers 22, 23. The third coil conductor 33 is formed between the insulator layers 23, 24. The fourth coil conductor 34 is formed between the insulator layers 24, 25. The fifth coil conductor 35 is formed between the insulator layers 25, 26. The sixth coil conductor 36 is formed between the insulator layers 26, 27.

The thickness T1 (refer to FIG. 1) of each coil conductor is less than the thickness of each insulator layer 20. In addition, the width W1 (refer to FIG. 1) of each coil conductor is less than the thickness of each insulator layer 20. As used herein, the “width W1” refers to, when the coil conductor is regarded as a single linear conductor, the width of the linear conductor.

Also, in top view, the distance E1 between the first coil conductor 31 and the second coil conductor 32 is greater than the width W1.

The six coil conductors are provided one to one for the six pad conductors 71-76, respectively. The second end of each coil conductor is electrically connected to its corresponding pad conductor. Two pad conductors arranged one on top of the other in the upward/downward direction are electrically connected to each other via the through hole conductor 61, 62, or 63. This allows two coil conductors to be electrically connected to each other in each of the first coil L1, the second coil L2, and the third coil L3.

In top view, each coil conductor has the shape formed by smoothly connecting a plurality of line segments via multiple arcs. As shown in FIG. 4, the first turn part of the third coil conductor 33 includes linear portions 33a, 33b, 33c, 33d, 33e, the second turn part thereof includes linear portions 33f, 33g, 33h, 33i, and the third turn part thereof includes linear portions 33j, 33k, 33l, 33m. These linear portions are connected to each other from outside toward inside the spiral in the order of 33a-33m. The portions 33a, 33c, 33e, 33g, 33i, 33k, and 33m are line segments aligned with the rightward/leftward direction. The portions 33b, 33d, 33f, 33h, 33j, and 33l are line segments aligned with the forward/backward direction. As shown in FIG. 3, each of the coil conductors other than the third coil conductor 33 has substantially the same configuration as the third coil conductor 33.

### (5) Positional Relationship Between a Plurality of Coil Conductors

As described above, the first interval I1 measured in the upward/downward direction from the upper surface 311 of the first coil conductor 31 to the lower surface 332 of the third coil conductor 33, the second interval I2 measured in the upward/downward direction from the upper surface 341 of the fourth coil conductor 34 to the lower surface 362 of the sixth coil conductor 36, and the third interval I3 measured in the upward/downward direction from the lower surface 332 of the third coil conductor 33 to the upper surface 341 of the fourth coil conductor 34 satisfy I1<I3 and I2<I3 and also satisfy I3≤I1+I2. The lengths of I1, I2, and I3 are adjusted by the respective thicknesses of the insulator layers 20.

As shown in FIG. 1, in a predetermined cross section taken parallel to the upward/downward direction (i.e., in the cross section shown in FIG. 1), a distance A1 and a distance B1 satisfy A1<B1. The distance A1 is a distance from an N^{th} turn part of the second coil conductor 32 to an N^{th} turn part of the first coil conductor 31. More specifically, the distance A1 is a distance from the outer periphery of the N^{th} turn part of the second coil conductor 32 to the inner periphery of the N^{th} turn part of the first coil conductor 31. The distance B1 is a distance from the N^{th} turn part of the second coil conductor 32 to an (N+1)^{th} turn part of the first coil conductor 31. More specifically, the distance B1 is a distance from the inner periphery of the N^{th} turn part of the second coil conductor 32 to the outer periphery of the (N+1)^{th} turn part of the first coil conductor 31. N is an arbitrary value as long as N is equal to or greater than 1 and N+1 is equal to or less than the number of turns of the first coil conductor 31. In this example, N=1, 2. Although only the first turn part and second turn part of each coil conductor are shown in FIG. 1, the positional relationship between the second turn part and the third turn part is the same as the positional relationship between the first turn part and the second turn part.

In addition, in a predetermined cross section taken parallel to the upward/downward direction (i.e., in the cross section shown in FIG. 1), a distance A2 and a distance B2 satisfy A2<B2. The distance A2 is a distance from the N^{th} turn part of the second coil conductor 32 to an N^{th} turn part of the third coil conductor 33. More specifically, the distance A2 is a distance from the outer periphery of the N^{th} turn part of the second coil conductor 32 to the inner periphery of the N^{th} turn part of the third coil conductor 33. The distance B2 is a distance from the N^{th} turn part of the second coil conductor 32 to an (N+1)th turn part of the third coil conductor 33. More specifically, the distance B2 is a distance from the inner periphery of the N^{th} turn part of the second coil conductor 32 to the outer periphery of the (N+1)^{th} turn part of the third coil conductor 33. N is an arbitrary value as long as N is equal to or greater than 1 and N+1 is equal to or less than the number of turns of the third coil conductor 33. In this example, N=1, 2.

Furthermore, in a predetermined cross section taken parallel to the upward/downward direction (i.e., in the cross section shown in FIG. 1), a distance C1 and a distance D1 satisfy C1<D1. The distance C1 is a distance from an N^{th} turn part of the fifth coil conductor 35 to an N^{th} turn part of the fourth coil conductor 34. More specifically, the distance C1 is a distance from the outer periphery of the N^{th} turn part of the fifth coil conductor 35 to the inner periphery of the N^{th} turn part of the fourth coil conductor 34. The distance D1 is a distance from the N^{th} turn part of the fifth coil conductor 35 to an (N+1)^{th} turn part of the fourth coil conductor 34. More specifically, the distance D1 is a distance from the inner periphery of the N^{th} turn part of the fifth coil conductor 35 to the outer periphery of the (N+1)^{th} turn part of the fourth coil conductor 34. N is an arbitrary value as long as N is equal to or greater than 1 and N+1 is equal to or less than the number of turns of the fourth coil conductor 34. In this example, N=1, 2.

Furthermore, in a predetermined cross section taken parallel to the upward/downward direction (i.e., in the cross section shown in FIG. 1), a distance C2 and a distance D2 satisfy C2<D2. The distance C2 is a distance from the N^{th} turn part of the fifth coil conductor 35 to an N^{th} turn part of the sixth coil conductor 36. More specifically, the distance C2 is a distance from the outer periphery of the N^{th} turn part of the fifth coil conductor 35 to the inner periphery of the N^{th} turn part of the sixth coil conductor 36. The distance D2 is a distance from the N^{th} turn part of the fifth coil conductor 35 to an (N+1)^{th} turn part of the sixth coil conductor 36. More specifically, the distance D2 is a distance from the inner periphery of the N^{th} turn part of the fifth coil conductor 35 to the outer periphery of the (N+1)^{th} turn part of the sixth coil conductor 36. N is an arbitrary value as long as N is equal to or greater than 1 and N+1 is equal to or less than the number of turns of the sixth coil conductor 36. In this example, N=1, 2.

Satisfying the inequalities A1<B1, A2<B2, C1<D1, and C2<D2 allows the common mode noise filter 1 to improve its ability to reduce the common mode noise.

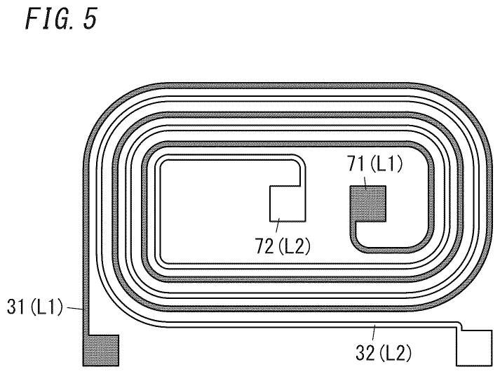

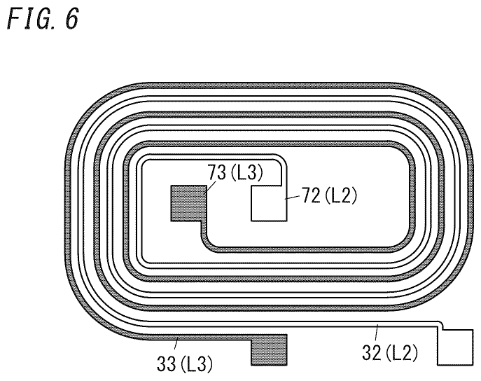

FIG. 5 is a top view schematically illustrating the first coil conductor 31 and the second coil conductor 32 projected onto a single plane. FIG. 6 is a top view schematically illustrating the third coil conductor 33 and the second coil conductor 32 projected onto a single plane. In top view, an N^{th} turn part of the second coil conductor 32 is provided between an N^{th} turn part and an (N+1)^{th} turn part of the first coil conductor 31. Likewise, in top view, the N^{th} turn part of the second coil conductor 32 is provided between an N^{th} turn part and an (N+1)^{th} turn part of the third coil conductor 33. In this example, N=1, 2.

In top view, the second coil conductor 32 is separated from both the first coil conductor 31 and the third coil conductor 33. In other words, in top view, neither part nor all of the second coil conductor 32 overlaps with any of the first coil conductor 31 or the third coil conductor 33. This contributes to improving the insulation reliability of the first coil conductor 31, the second coil conductor 32, and the third coil conductor 33.

On the other hand, in top view, the first coil conductor 31 and the third coil conductor 33 mostly overlap with each other. To say the least, the first coil conductor 31 and the third coil conductor 33 overlap with each other for one turn parts thereof or more. Refer to FIGS. 3 and 4, and it can be seen that the linear portions 33b-33l of the third coil conductor 33 overlap with their counterparts of the first coil conductor 31.

An N^{th} turn part of the fourth coil conductor 34 is provided between an N^{th} turn part and an (N+1)^{th} turn part of the fifth coil conductor 35. Likewise, an N^{th} turn part of the sixth coil conductor 36 is provided between the N^{th} turn part and the (N+1)^{th} turn part of the fifth coil conductor 35. In this example, N=1, 2.

In top view, the fifth coil conductor 35 is separated from both the fourth coil conductor 34 and the sixth coil conductor 36. In other words, in top view, neither part nor all of the fifth coil conductor 35 overlaps with any of the fourth coil conductor 34 or the sixth coil conductor 36. This contributes to improving the insulation reliability of the fourth coil conductor 34, the fifth coil conductor 35, and the sixth coil conductor 36.

On the other hand, in top view, the fourth coil conductor 34 and the sixth coil conductor 36 mostly overlap with each other. To say the least, the fourth coil conductor 34 and the sixth coil conductor 36 overlap with each other for one turn parts thereof or more.

The area in which the first coil conductor 31 and the third coil conductor 33 face each other in the upward/downward direction is larger than the area in which the first coil conductor 31 and the second coil conductor 32 face each other in the upward/downward direction. The stray capacitance produced between the first coil conductor 31 and the third coil conductor 33 is greater than the stray capacitance produced between the first coil conductor 31 and the second coil conductor 32.

The area in which the first coil conductor 31 and the third coil conductor 33 face each other in the upward/downward direction is larger than the area in which the third coil conductor 33 and the second coil conductor 32 face each other in the upward/downward direction. The stray capacitance produced between the first coil conductor 31 and the third coil conductor 33 is greater than the stray capacitance produced between the third coil conductor 33 and the second coil conductor 32.

The area in which the fourth coil conductor 34 and the sixth coil conductor 36 face each other in the upward/downward direction is larger than the area in which the fourth coil conductor 34 and the fifth coil conductor 35 face each other in the upward/downward direction. The stray capacitance produced between the fourth coil conductor 34 and the sixth coil conductor 36 is greater than the stray capacitance produced between the fourth coil conductor 34 and the fifth coil conductor 35.

The area in which the fourth coil conductor 34 and the sixth coil conductor 36 face each other in the upward/downward direction is larger than the area in which the sixth coil conductor 36 and the fifth coil conductor 35 face each other in the upward/downward direction. The stray capacitance produced between the fourth coil conductor 34 and the sixth coil conductor 36 is greater than the stray capacitance produced between the sixth coil conductor 36 and the fifth coil conductor 35.

The area in which the third coil conductor 33 and the fourth coil conductor 34 face each other in the upward/downward direction is larger than the area in which the third coil conductor 33 and the second coil conductor 32 face each other in the upward/downward direction.

### (6) Evaluation of Mode Conversion Characteristics

### (6.1) First Evaluation

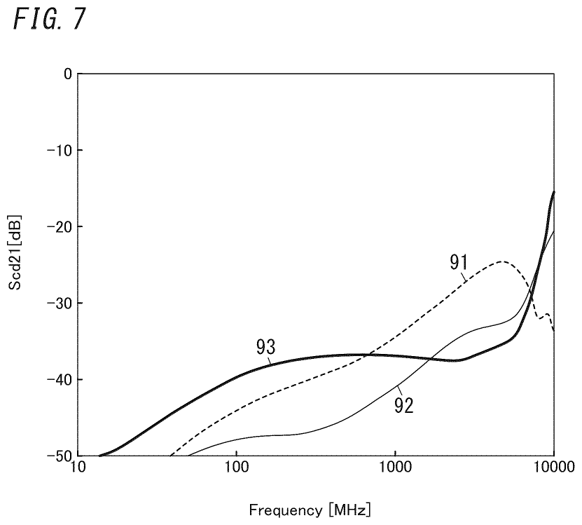

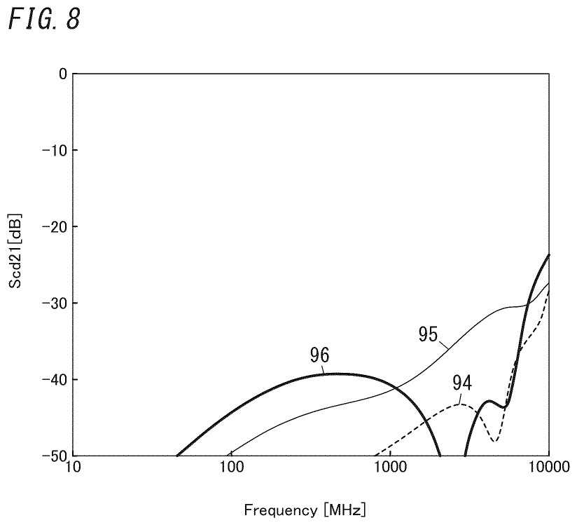

FIG. 7 shows differential/common mode conversion characteristics (three Scd21) of a common mode noise filter according to a first comparative example. FIG. 8 shows three Scd21 of a common mode noise filter according to a first reference example.

In the common mode noise filter according to the first reference example and the common mode noise filter according to the first comparative example, as well as in the common mode noise filter 1 according to the exemplary embodiment, the first coil L1 includes the first coil conductor 31 and the fourth coil conductor 34, the second coil L2 includes the second coil conductor 32 and the fifth coil conductor 35, and the third coil L3 includes third coil conductor 33 and the sixth coil conductor 36.

The common mode noise filter according to the first reference example satisfies the following condition, while the common mode noise filter according to the first comparative example does not satisfy the following condition:

I1<I3,I2<I3, and I3≤I1+I2

In each of FIGS. 7 and 8, the three Scd21 are: Scd21 corresponding to a differential signal between the output signal of the first coil L1 and the output signal of the second coil L2; Scd21 corresponding to a differential signal between the output signal of the second coil L2 and the output signal of the third coil L3; and Scd21 corresponding to a differential signal between the output signal of the third coil L3 and the output signal of the first coil L1. The curve 91 represents one of the three Scd21, the curve 92 represents another one of the three Scd21, and the curve 93 represents the other of the three Scd21. In the same way, the curve 94 represents one of the three Scd21, the curve 95 represents another one of the three Scd21, and the curve 96 represents the other of the three Scd21.

It can be said that the broader the range where Scd21 remains relatively small is, the better the mode conversion characteristic is. As shown in FIGS. 7 and 8, the common mode noise filter according to the first reference example has smaller Scd21 around the range from 1000 MHz to 8000 MHz and exhibits better mode conversion characteristic than the common mode noise filter according to the first comparative example. This is because the common mode noise filter according to the first reference example satisfies the above-described condition and therefore may reduce the dispersion in stray capacitance from one coil to another, compared to the common mode noise filter according to the first comparative example. That is why the common mode noise filter 1 according to the exemplary embodiment, which also satisfies the above-described condition as well as the common mode noise filter according to the first reference example, would also achieve the advantage of improving the mode conversion characteristic.

### (6.2) Second Evaluation

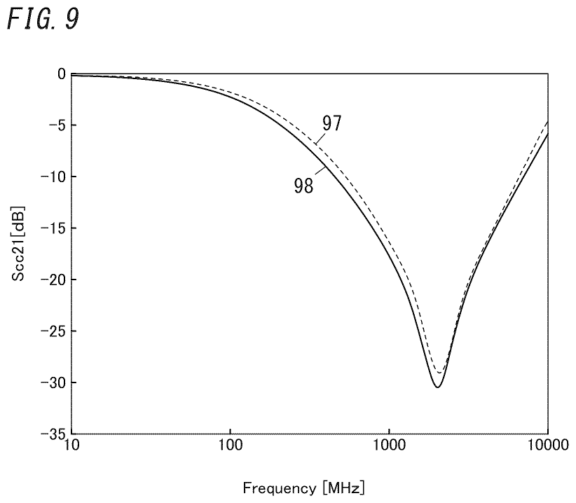

FIG. 9 shows a curve 97 representing the magnitude of common mode attenuation (Scc21) of a common mode noise filter according to a second comparative example and a curve 98 representing Scc21 of a common mode noise filter according to a second reference example. The common mode noise filter according to the second reference example satisfies A1<B1, A2<B2, C1<D1, and D2<D2, while the common mode noise filter according to the second comparative example fails to satisfy this condition. In the other respects, the second comparative example and the second reference example have the same configuration.

It can be said that the broader the range where Scc21 remains relatively small is, the better the common mode noise reduction performance is. As shown in FIG. 9, the second reference example has smaller Scc21 than the second comparative example. That is why the common mode noise filter 1 according to the exemplary embodiment, which also satisfies the above-described condition as well as the common mode noise filter according to the second reference example, would also achieve the advantage of improving the common mode noise reduction performance while maintaining its mode conversion characteristics.

### (First Variation)

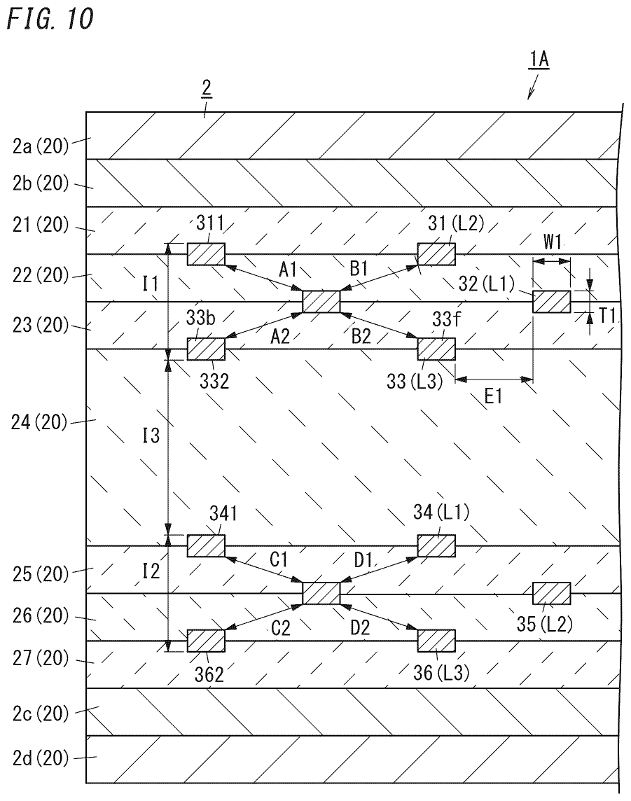

A common mode noise filter 1A according to a first variation will be described with reference to FIGS. 10-12. In the following description, any constituent element of this first variation, having the same function as a counterpart of the embodiment described above, will be designated by the same reference numeral as that counterpart's, and description thereof will be omitted herein.

### (1) Configuration

In the common mode noise filter 1A according to this variation, the plurality of coil conductors are connected differently from the common mode noise filter 1 according to the exemplary embodiment described above. More specifically, the first coil conductor 31 is electrically connected to the fifth coil conductor 35 and the second coil conductor 32 is electrically connected to the fourth coil conductor 34.

That is to say, in the common mode noise filter 1A according to this first variation, the first coil L1 includes the second coil conductor 32 and the fourth coil conductor 34 electrically connected to the second coil conductor 32. The second coil L2 includes the first coil conductor 31 and the fifth coil conductor 35 electrically connected to the first coil conductor 31. The third coil L3 includes the third coil conductor 33 and the sixth coil conductor 36 electrically connected to the third coil conductor 33.

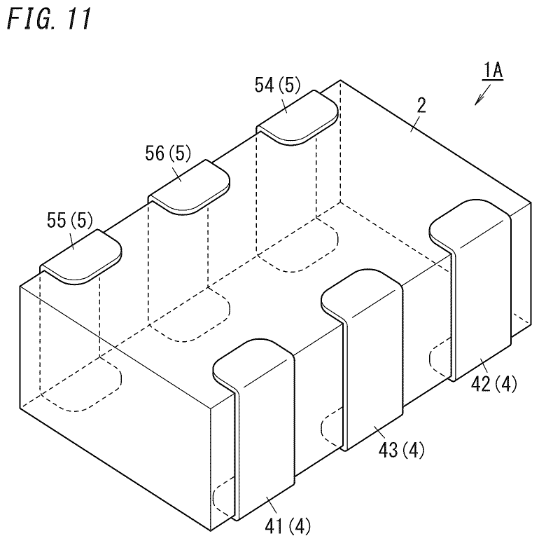

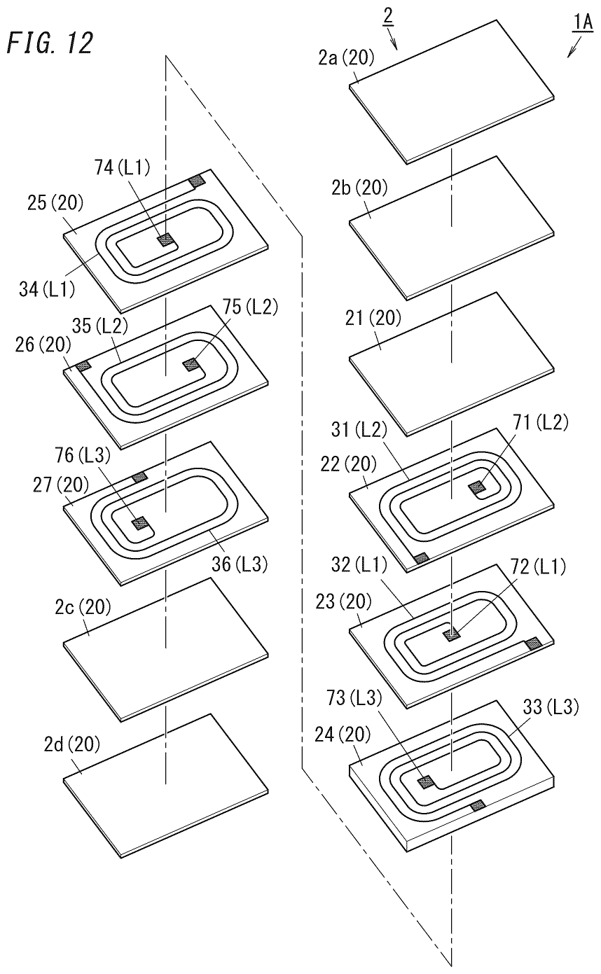

In this first variation, the plurality of coil conductors are connected differently from in the exemplary embodiment described above. Thus, the fourth coil conductor 34 and the fifth coil conductor 35 of the common mode noise filter 1A have slightly different shapes (refer to FIG. 12) from their counterparts shown in FIG. 3. In addition, since the shapes of the fourth coil conductor 34 and the fifth coil conductor 35 are changed, the arrangement of the three second terminals 5 (refer to FIG. 11) is different from the arrangement shown in FIG. 2.

The through hole conductor 61 electrically connects the second coil conductor 32 and the fourth coil conductor 34 to each other. The through hole conductor 62 electrically connects the first coil conductor 31 and the fifth coil conductor 35 to each other. The through hole conductor 63 electrically connects the third coil conductor 33 and the sixth coil conductor 36 to each other.

In the common mode noise filter 1 according to the exemplary embodiment described above, the first coil conductor 31 of the first coil L1 and the third coil conductor 33 of the third coil L3 face each other in the upward/downward direction as shown in FIG. 1. In addition, the fourth coil conductor 34 of the first coil L1 and the sixth coil conductor 36 of the third coil L3 face each other in the upward/downward direction. The stray capacitance is produced between each pair of coil conductors facing each other. Note that although the third coil conductor 33 and the fourth coil conductor 34 also face each other in the upward/downward direction, their interval is so wide, and the stray capacitance produced between them is so small that this pair of coil conductors is ignored in this case.

On the other hand, in the common mode noise filter 1A according to this first variation, the first coil conductor 31 of the second coil L2 and the third coil conductor 33 of the third coil L3 face each other in the upward/downward direction as shown in FIG. 10. In addition, the fourth coil conductor 34 of the first coil L1 and the sixth coil conductor 36 of the third coil L3 also face each other in the upward/downward direction. The stray capacitance is produced between each pair of coil conductors facing each other.

In the exemplary embodiment described above, two coil conductors face each other in the upward/downward direction at two points, each of which is a point where a coil conductor of the first coil L1 and a coil conductor of the third coil L3 face each other. That is why the stray capacitance is produced mainly between the first coil L1 and the third coil L3 and the stray capacitance produced between the first coil L1 and the second coil L2 and the stray capacitance produced between the second coil L2 and the third coil L3 are relatively small. Consequently, a (third) differential signal between the output signal of the first coil L1 and the output signal of the third coil L3 deteriorates more significantly than the first differential signal and the second differential signal. As can be seen, such more significant deterioration of one differential signal than the other differential signals causes the balance between the first to third differential signals to be lost, thus possibly causing a decline in the mode conversion characteristics.

In this first variation, there are also two points where two coil conductors face each other in the upward/downward direction. One of the two points is a point where a coil conductor of the second coil L2 and a coil conductor of the third coil L3 face each other. The other point is a point where a coil conductor of the first coil L1 and a coil conductor of the third coil L3 face each other. That is to say, the two stray capacitances produced between the first coil L1 and the third coil L3 in the exemplary embodiment described above are distributed as the stray capacitance produced between the second coil L2 and the third coil L3 and the stray capacitance produced between the first coil L1 and the third coil L3 in this first variation. As can be seen, reducing the dispersion in stray capacitance improves the balance between the differential signals, thus reducing the chances of causing a decline in mode conversion characteristics.

Note that the stray capacitance is also produced between two obliquely facing coil conductors (e.g., between the first coil conductor 31 and the second coil conductor 32). This stray capacitance is less than the stray capacitance produced between two coil conductors facing each other in the upward/downward direction. This is because the direction in which the two coil conductors face each other is oblique to a normal to each coil conductor, and therefore, the effective facing area contributing to the stray capacitance decreases. That is why only the stray capacitance produced between two coil conductors facing each other in the upward/downward direction is taken into account in the foregoing description.

### (2) Evaluation of Mode Conversion Characteristics

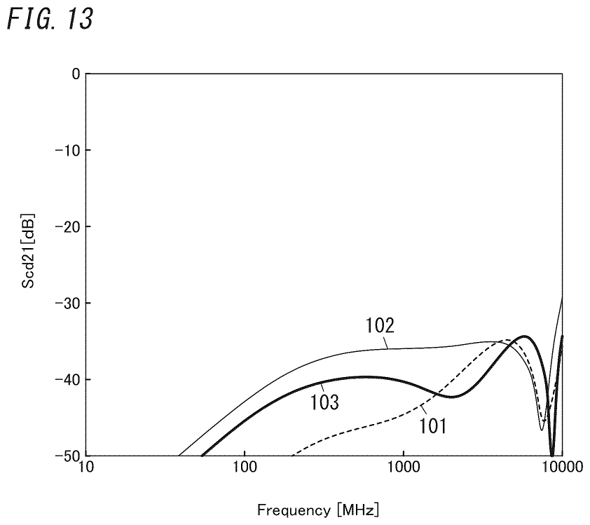

FIG. 13 shows three Scd21 of a common mode noise filter according to a third reference example. In the common mode noise filter according to the third reference example, as well as the common mode noise filter 1A according to the first variation, the first coil L1 includes the second coil conductor 32 and the fourth coil conductor 34, the second coil L2 includes the first coil conductor 31 and the fifth coil conductor 35, and the third coil L3 includes the third coil conductor 33 and the sixth coil conductor 36 (refer to FIG. 12).

The common mode noise filter according to the third reference example satisfies the following condition:

I1<I3,I2<I3,and I3≤I1+I2

That is to say, in the common mode noise filter according to the third reference example, the respective coil conductors are connected differently from the common mode noise filter according to the first reference example (refer to FIGS. 3 and 8). Thus, in the common mode noise filter according to the third reference example (refer to FIG. 12), the fourth coil conductor 34 and the fifth coil conductor 35 have slightly different shapes from their counterparts shown in FIG. 3. In addition, since the shapes of the fourth coil conductor 34 and the fifth coil conductor 35 are changed, the arrangement of the three second terminals 5 (refer to FIG. 11) is different from the arrangement shown in FIG. 2. In the other respects, the common mode noise filter according to the third reference example has the same configuration as the common mode noise filter according to the first reference example.

The curves 101-103 shown in FIG. 13, as well as the curves 94-96 shown in FIG. 8, also represent Scd21 corresponding to the respective differential signals. As shown in FIG. 13, the common mode noise filter according to the third reference example has a smaller Scd21 around the range from 1000 MHz to 8000 MHz and exhibits a better mode conversion characteristic than the common mode noise filter according to the first reference example (refer to FIG. 8). Thus, the common mode noise filter 1A according to this first variation which satisfies the above-described condition as well as the common mode noise filter according to the third reference example would achieve an even better mode conversion characteristic than the common mode noise filter 1 according to the exemplary embodiment described above.

### Other Variations of Embodiment

Next, variations of the exemplary embodiment will be enumerated one after another. Note that the variations to be described below may be adopted in combination as appropriate. Optionally, the variations to be described below may be adopted in combination with either the exemplary embodiment described above or the first variation described above, whichever is appropriate.

Two or more insulator layers 24 may be provided between the third coil conductor 33 and the fourth coil conductor 34.

The numbers of turns of the coil conductors described above are only examples and should not be construed as limiting.

The three first terminals 4 and the three second terminals 5 may form part of the coil conductors.

In the foregoing description, if one of two values being compared with each other is “equal to or greater than” the other, this phrase may herein cover both a situation where these two values are equal to each other and a situation where one of the two values is greater than the other. However, this should not be construed as limiting. Alternatively, the phrase “equal to or greater than” may also be a synonym of the phrase “greater than” that covers only a situation where one of the two values is over the other. That is to say, it is arbitrarily changeable, depending on selection of a reference value or any preset value, whether or not the phrase “equal to or greater than” covers the situation where the two values are equal to each other. Therefore, from a technical point of view, there is no difference between the phrase “equal to or greater than” and the phrase “greater than.” Similarly, the phrase “equal to or less than” may be a synonym of the phrase “less than” as well.

Also, in the foregoing description, even if two values are described as being “equal to each other,” the two values do not have to be exactly equal to each other but may also be different from each other within a practically tolerable range. For example, if the difference between two values is less than 5%, then the present disclosure is applicable with the two values regarded as substantially equal to each other.

### Recapitulation

The exemplary embodiment and its variations described above are specific implementations of the following aspects of the present disclosure.

A common mode noise filter (1, 1A) according to a first aspect includes: a plurality of insulator layers (20) stacked one on top of another in an upward/downward direction; and a first coil conductor (31), a second coil conductor (32), a third coil conductor (33), a fourth coil conductor (34), a fifth coil conductor (35), and a sixth coil conductor (36) provided for the plurality of insulator layers (20). A first coil (L1), a second coil (L2), and a third coil (L3) are formed by the first coil conductor (31), the second coil conductor (32), the third coil conductor (33), the fourth coil conductor (34), the fifth coil conductor (35), and the sixth coil conductor (36). The first coil (L1) is formed by electrically connecting one coil conductor selected from the group consisting of the first coil conductor (31) and the second coil conductor (32) to the fourth coil conductor (34).

The second coil (L2) is formed by electrically connecting a remaining coil conductor selected from the group consisting of the first coil conductor (31) and the second coil conductor (32) to one coil conductor selected from the group consisting of the fifth coil conductor (35) and the sixth coil conductor (36). The third coil (L3) is formed by electrically connecting the third coil conductor (33) to a remaining coil conductor selected from the group consisting of the fifth coil conductor (35) and the sixth coil conductor (36). The first coil conductor (31), the second coil conductor (32), the third coil conductor (33), the fourth coil conductor (34), the fifth coil conductor (35), and the sixth coil conductor (36) are arranged in this order from top to bottom. A first interval (I1) measured in the upward/downward direction from an upper surface (311) of the first coil conductor (31) to a lower surface (332) of the third coil conductor (33), a second interval (I2) measured in the upward/downward direction from an upper surface (341) of the fourth coil conductor (34) to a lower surface (362) of the sixth coil conductor (36), and a third interval (I3) measured in the upward/downward direction from the lower surface (332) of the third coil conductor (33) to the upper surface (341) of the fourth coil conductor (34) satisfy I1<I3 and I2<I3.

This configuration may reduce the chances of causing a decline in the mode conversion characteristics of the common mode noise filter (1, 1A).

A common mode noise filter (1, 1A) according to a second aspect, which may be implemented in conjunction with the first aspect, satisfies I3≤I1+I2.

This configuration may reduce at least one of the stray capacitance produced between the first coil conductor (31) and the third coil conductor (33) or the stray capacitance produced between the fourth coil conductor (34) and the sixth coil conductor (36), thus further reducing the chances of causing a decline in the mode conversion characteristics of the common mode noise filter (1, 1A).

In a common mode noise filter (1) according to a third aspect, which may be implemented in conjunction with the first or second aspect, the first coil (L1) includes the first coil conductor (31) and the fourth coil conductor (34). The fourth coil conductor (34) is electrically connected to the first coil conductor (31). The second coil (L2) includes the second coil conductor (32) and the fifth coil conductor (35). The fifth coil conductor (35) is electrically connected to the second coil conductor (32). The third coil (L3) includes the third coil conductor (33) and the sixth coil conductor (36). The sixth coil conductor (36) is electrically connected to the third coil conductor (33).

This configuration may reduce the chances of causing a decline in the mode conversion characteristics of the common mode noise filter (1).

In a common mode noise filter (1A) according to a fourth aspect, which may be implemented in conjunction with the first or second aspect, the first coil (L1) includes the second coil conductor (32) and the fourth coil conductor (34). The fourth coil conductor (34) is electrically connected to the second coil conductor (32). The second coil (L2) includes the first coil conductor (31) and the fifth coil conductor (35). The fifth coil conductor (35) is electrically connected to the first coil conductor (31). The third coil (L3) includes the third coil conductor (33) and the sixth coil conductor (36). The sixth coil conductor (36) is electrically connected to the third coil conductor (33).

This configuration may reduce dispersion in stray capacitance, thus further reducing the chances of causing a decline in the mode conversion characteristics of the common mode noise filter (1A).

In a common mode noise filter (1, 1A) according to a fifth aspect, which may be implemented in conjunction with any one of the first to fourth aspects, in a predetermined cross section taken parallel to the upward/downward direction, a distance (A1) from an N^{th} turn part of the second coil conductor (32) to an N^{th} turn part of the first coil conductor (31) and a distance (B1) from the N^{th} turn part of the second coil conductor (32) to an (N+1)^{th} turn part of the first coil conductor (31) satisfy A1<B1, where N is an arbitrary value as long as N is equal to or greater than 1 and N+1 is equal to or less than the number of turns of the first coil conductor (31).

This configuration may improve the common mode noise reduction performance of the common mode noise filter (1, 1A) while allowing the common mode noise filter (1, 1A) to maintain its mode conversion characteristics.

In a common mode noise filter (1, 1A) according to a sixth aspect, which may be implemented in conjunction with any one of the first to fifth aspects, in a predetermined cross section taken parallel to the upward/downward direction, a distance (A2) from an N^{th} turn part of the second coil conductor (32) to an N^{th} turn part of the third coil conductor (33) and a distance (B2) from the N^{th} turn part of the second coil conductor (32) to an (N+1)^{th} turn part of the third coil conductor (33) satisfy A2<B2, where N is an arbitrary value as long as N is equal to or greater than 1 and N+1 is equal to or less than the number of turns of the third coil conductor (33).

This configuration may improve the common mode noise reduction performance of the common mode noise filter (1, 1A) while allowing the common mode noise filter (1, 1A) to maintain its mode conversion characteristics.

In a common mode noise filter (1, 1A) according to a seventh aspect, which may be implemented in conjunction with any one of the first to sixth aspects, in a predetermined cross section taken parallel to the upward/downward direction, a distance (C1) from an N^{th} turn part of the fifth coil conductor (35) to an N^{th} turn part of the fourth coil conductor (34) and a distance (D1) from the N^{th} turn part of the fifth coil conductor (35) to an (N+1)^{th} turn part of the fourth coil conductor (34) satisfy C1<D1, where N is an arbitrary value as long as N is equal to or greater than 1 and N+1 is equal to or less than the number of turns of the fourth coil conductor (34).

This configuration may improve the common mode noise reduction performance of the common mode noise filter (1, 1A) while allowing the common mode noise filter (1, 1A) to maintain its mode conversion characteristics.

In a common mode noise filter (1, 1A) according to an eighth aspect, which may be implemented in conjunction with any one of the first to seventh aspects, in a predetermined cross section taken parallel to the upward/downward direction, a distance (C2) from an N^{th} turn part of the fifth coil conductor (35) to an N^{th} turn part of the sixth coil conductor (36) and a distance (D2) from the N^{th} turn part of the fifth coil conductor (35) to an (N+1)^{th} turn part of the sixth coil conductor (36) satisfy C2<D2, where N is an arbitrary value as long as N is equal to or greater than 1 and N+1 is equal to or less than the number of turns of the sixth coil conductor (36).

This configuration may improve the common mode noise reduction performance of the common mode noise filter (1, 1A) while allowing the common mode noise filter (1, 1A) to maintain its mode conversion characteristics.

In a common mode noise filter (1, 1A) according to a ninth aspect, which may be implemented in conjunction with any one of the first to eighth aspects, in top view, the second coil conductor (32) is separated from both the first coil conductor (31) and the third coil conductor (33).

This configuration may improve the insulation reliability of the coil conductors.

In a common mode noise filter (1, 1A) according to a tenth aspect, which may be implemented in conjunction with any one of the first to ninth aspects, in top view, the fifth coil conductor (35) is separated from both the fourth coil conductor (34) and the sixth coil conductor (36).

This configuration may improve the insulation reliability of the coil conductors.

Note that the constituent elements according to the second to tenth aspects are not essential constituent elements for the common mode noise filter (1, 1A) but may be omitted as appropriate.

### REFERENCE SIGNS LIST

1, 1A Common Mode Noise Filter
20 Insulator Layer
31 First Coil Conductor
32 Second Coil Conductor
33 Third Coil Conductor
34 Fourth Coil Conductor
35 Fifth Coil Conductor
36 Sixth Coil Conductor
311 Upper Surface
332 Lower Surface
341 Upper Surface
362 Lower Surface
A1 Distance
A2 Distance
B1 Distance
B2 Distance
C1 Distance
C2 Distance
D1 Distance
D2 Distance
I1 First Interval
I2 Second Interval
I3 Third Interval
L1 First Coil
L2 Second Coil
L3 Third Coil

1. A common mode noise filter comprising:
a plurality of insulator layers stacked one on top of another in an upward/downward direction; and
a first coil conductor, a second coil conductor, a third coil conductor, a fourth coil conductor, a fifth coil conductor, and a sixth coil conductor provided for the plurality of insulator layers,
a first coil, a second coil, and a third coil being formed by the first coil conductor, the second coil conductor, the third coil conductor, the fourth coil conductor, the fifth coil conductor, and the sixth coil conductor,
the first coil being formed by electrically connecting one coil conductor selected from the group consisting of the first coil conductor and the second coil conductor to the fourth coil conductor,
the second coil being formed by electrically connecting a remaining coil conductor selected from the group consisting of the first coil conductor and the second coil conductor to one coil conductor selected from the group consisting of the fifth coil conductor and the sixth coil conductor,
the third coil being formed by electrically connecting the third coil conductor to a remaining coil conductor selected from the group consisting of the fifth coil conductor and the sixth coil conductor,
the first coil conductor, the second coil conductor, the third coil conductor, the fourth coil conductor, the fifth coil conductor, and the sixth coil conductor being arranged in this order from top to bottom, and
a first interval I1 measured in the upward/downward direction from an upper surface of the first coil conductor to a lower surface of the third coil conductor, a second interval I2 measured in the upward/downward direction from an upper surface of the fourth coil conductor to a lower surface of the sixth coil conductor, and a third interval I3 measured in the upward/downward direction from the lower surface of the third coil conductor to the upper surface of the fourth coil conductor satisfying I1<I3 and I2<I3.

2. The common mode noise filter of claim 1, wherein
the common mode noise filter satisfies I3≤I1+I2.

3. The common mode noise filter of claim 1, wherein
the first coil includes the first coil conductor and the fourth coil conductor electrically connected to the first coil conductor,
the second coil includes the second coil conductor and the fifth coil conductor electrically connected to the second coil conductor, and
the third coil includes the third coil conductor and the sixth coil conductor electrically connected to the third coil conductor.

4. The common mode noise filter of claim 1, wherein
the first coil includes the second coil conductor and the fourth coil conductor electrically connected to the second coil conductor,
the second coil includes the first coil conductor and the fifth coil conductor electrically connected to the first coil conductor, and
the third coil includes the third coil conductor and the sixth coil conductor electrically connected to the third coil conductor.

5. The common mode noise filter of claim 1, wherein
in a predetermined cross section taken parallel to the upward/downward direction,
a distance A1 from an N^{th} turn part of the second coil conductor to an N^{th} turn part of the first coil conductor and
a distance B1 from the N^{th} turn part of the second coil conductor to an (N+1)^{th} turn part of the first coil conductor
satisfy A1<B1,
where N is an arbitrary value as long as N is equal to or greater than 1 and N+1 is equal to or less than a numerical number of turns of the first coil conductor.

6. The common mode noise filter of claim 1, wherein
in a predetermined cross section taken parallel to the upward/downward direction,
a distance A2 from an N^{th} turn part of the second coil conductor to an N^{th} turn part of the third coil conductor and
a distance B2 from the N^{th} turn part of the second coil conductor to an (N+1)^{th} turn part of the third coil conductor
satisfy A2<B2,
where N is an arbitrary value as long as N is equal to or greater than 1 and N+1 is equal to or less than a numerical number of turns of the third coil conductor.

7. The common mode noise filter of claim 1, wherein
in a predetermined cross section taken parallel to the upward/downward direction,
a distance C1 from an N^{th} turn part of the fifth coil conductor to an N^{th} turn part of the fourth coil conductor and
a distance D1 from the N^{th} turn part of the fifth coil conductor to an (N+1)^{th} turn part of the fourth coil conductor
satisfy C1<D1,
where N is an arbitrary value as long as N is equal to or greater than 1 and N+1 is equal to or less than a numerical number of turns of the fourth coil conductor.

8. The common mode noise filter of claim 1, wherein
in a predetermined cross section taken parallel to the upward/downward direction,
a distance C2 from an N^{th} turn part of the fifth coil conductor to an N^{th} turn part of the sixth coil conductor and
a distance D2 from the N^{th} turn part of the fifth coil conductor to an (N+1)^{th} turn part of the sixth coil conductor
satisfy C2<D2,
where N is an arbitrary value as long as N is equal to or greater than 1 and N+1 is equal to or less than a numerical number of turns of the sixth coil conductor.

9. The common mode noise filter of claim 1, wherein
in top view, the second coil conductor is separated from both the first coil conductor and the third coil conductor.

10. The common mode noise filter of claim 1, wherein
in top view, the fifth coil conductor is separated from both the fourth coil conductor and the sixth coil conductor.
